(19) United States
(12) Patent Application Publication
(10) Pub. No.: US 2025/0284215 A1
(43) Pub. Date: Sep. 11, 2025

(54) SYSTEMS AND METHODS FOR OPTIMIZING METROLOGY MARKS

(71) Applicant: ASML NETHERLANDS B.V., Veldhoven (NL)

(72) Inventors: Syam Parayil VENUGOPALAN, Eindhoven (NL); Matthieu BESEMER, Veldhoven (NL); Seheon KIM, San Jose, CA (US)

(73) Assignee: ASML NETHERLANDS B.V., Veldhoven (NL)

(21) Appl. No.: 18/863,680

(22) PCT Filed: Jul. 14, 2023
(86) PCT No.: PCT/EP2023/069733

§ 371 Date: Nov. 7, 2024

Related U.S. Application Data
(60) Provisional application No. 63/390,459, filed on Jul. 19, 2022.

(51) Int. Cl. G03F 9/00; G03F 7/00

(52) U.S. Cl. CPC G03F 9/7073; G03F 7/705; G03F 7/70625; G03F 7/70633; G03F 7/70683

(57) ABSTRACT

Systems, methods, and computer software are disclosed for optimizing a metrology mark. One method includes simulating an etch process based on one or more selected from: a pattern density, a microloading effect induced intra-mark variation, or a sensitivity of intra-mark variation to etch chemistry. The method can predict etch-induced process effects on the metrology mark based on the simulation of the etch process and optimize the metrology mark based on the predicted etch-induced process effects.

### CROSS-REFERENCE TO RELATED APPLICATIONS

This application claims priority of U.S. application 63/390,459 which was filed on Jul. 19, 2022 and which is incorporated herein in its entirety by reference.

### TECHNICAL FIELD

The description herein relates generally to design and optimization of etched metrology marks. More particularly, the disclosure includes apparatus, methods, and computer programs for optimizing metrology marks utilizing simulations that account for physical and chemical effects on the etching process.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g., comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus may also be referred to as a stepper. In an alternative apparatus, a step-and-scan apparatus can cause a projection beam to scan over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is can be referred to as low-k1 lithography, according to the resolution formula CD=k1×λ/NA, where λ is the wavelength of radiation employed (e.g., 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

Systems, methods, and computer software are disclosed for optimizing a metrology mark. In one aspect, a method includes simulating an etch process based on one or more of a pattern density, a microloading effect induced intra-mark variation, or a sensitivity of intra-mark variation to etch chemistry. The method can predict etch-induced process effects on the metrology mark based on the simulation of the etch process and optimize the metrology mark based on the predicted etch-induced process effects.

In some variations, an etch rate in the simulation can be based at least partially on a function of a CD with coefficients in the function being dependent on the etch chemistry. The function can be an exponential term having the coefficients, the function determining, in part, an etch load for the etch process.

In some variations, the microloading effect induced intra-mark variation can include a CD or a side wall angle or floor tilt of the metrology mark being larger or smaller than an ideal metrology mark. For example, such microloading effect induced intra-mark variation can be based on the pattern density. Also, determining the sensitivity of intra-mark variation to etch chemistry can include determining an etch rate based on the etch regime being normal lag or reverse lag as determined by the etch chemistry.

In some variations, optimizing the metrology mark can include optimizing a metrology mark placement based on an intra-die overlay fingerprint produced from the simulating of the etch process at a first length scale. This can also include obtaining a metrology mark design and the metrology mark placement in a die, inputting the metrology mark design into the simulation at the first length scale, extracting critical zones in a die based on the intra-die overlay fingerprint determined by the simulation, and optimizing the metrology mark placement, while avoiding the critical zones, to minimize the intra-die overlay fingerprint.

In some variations, the metrology mark design can be based on one or more of a CD, pitch, segmentation, or surrounding fill structures. The simulation can be further based on inputting stack information of the metrology mark design, the stack information including layers in the die. The inputting of the metrology mark design can include determining an etch regime, where the simulation can be based on the etch regime being normal lag or reverse lag.

In some variations, optimizing the metrology mark can include optimizing a metrology mark design based on an intra-mark overlay fingerprint produced from the simulating the etch process at a second length scale. This can include obtaining the metrology mark design and the metrology mark placement in a die, inputting the metrology mark design into the simulation at the second length scale, extracting the intra-mark overlay fingerprint from the simulation at the second length scale, and optimizing the metrology mark design to reduce the intra-mark overlay fingerprint.

In some variations, the optimizing of the metrology mark placement can include optimizing one or more of a CD, pitch, design, and segmentation of the metrology mark and can also include optimizing a surrounding fill pattern to reduce an intra-mark variation.

In some variations, a method can include inputting ideal metrology marks, determining a floor tilt map, a side wall angle map, a CD map, and a etch depth map based on the predicting of the etch-induced process effects for each of the ideal metrology marks, generating three-dimensional representations of the after-etched mark geometry based on the floor tilt map, the side wall angle map, the CD map, and the etch depth map, and determining a combination of the ideal metrology marks that improve a performance of a die utilizing the combination, the performance determined based at least on the three-dimensional representations.

In some variations, improving the performance includes reducing an alignment position deviation and the performance can be determined utilizing a finite-difference time domain optical solver.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates a block diagram of various subsystems of a lithographic projection apparatus, according to an embodiment of the present disclosure.

FIG. 2 illustrates an exemplary flow chart for simulating lithography in a lithographic projection apparatus, according to an embodiment of the present disclosure.

FIG. 3 illustrates metrology marks on a die having varying pattern densities, according to an embodiment of the present disclosure.

FIG. 4 illustrates a simplified etching process, according to an embodiment of the present disclosure.

FIG. 5 illustrates the effect of feature size on etch rate, according to an embodiment of the present disclosure.

FIG. 6 illustrates the effect of neighboring pattern density on the etch performance of a metrology mark, according to an embodiment of the present disclosure.

FIG. 7 illustrates a process for optimizing a metrology mark, according to an embodiment of the present disclosure.

FIG. 8 illustrates a process for optimizing a metrology mark placement, according to an embodiment of the present disclosure.

FIG. 9 illustrates a process for optimizing a metrology mark design, according to an embodiment of the present disclosure.

FIG. 10 is a diagram illustrating a metrology mark with variations in CD, floor tilt and side wall angle, according to an embodiment of the present disclosure.

FIG. 11 is a diagram illustrating a process for optimizing a metrology mark design, according to an embodiment of the present disclosure.

FIG. 12 is a block diagram of an example computer system, according to an embodiment of the present disclosure.

FIG. 13 is a schematic diagram of a lithographic projection apparatus, according to an embodiment of the present disclosure.

FIG. 14 is a schematic diagram of another lithographic projection apparatus, according to an embodiment of the present disclosure.

FIG. 15 is a detailed view of the lithographic projection apparatus, according to an embodiment of the present disclosure.

FIG. 16 is a detailed view of the source collector module of the lithographic projection apparatus, according to an embodiment of the present disclosure.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic methods.

An example of a programmable LCD array is given in U.S. Pat. No. 5,229,872, which is incorporated herein by reference.

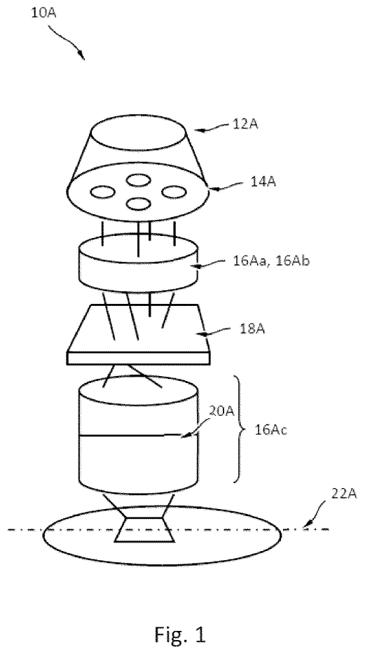

FIG. 1 illustrates a block diagram of various subsystems of a lithographic projection apparatus 10A, according to an embodiment of the present disclosure. Major components are a radiation source 12A, which may be a deep-ultraviolet excimer laser source or other type of source including an extreme ultraviolet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin (Θmax), wherein n is the refractive index of the media between the substrate and the last element of the projection optics, and Θmax is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

According to an embodiment of the present disclosure, one or more images may be generated. The images includes various types of signal that may be characterized by pixel values or intensity values of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image. In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be signal having intensity less than 50% of the highest intensity of the pixel (e.g., pixels corresponding to target pattern may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

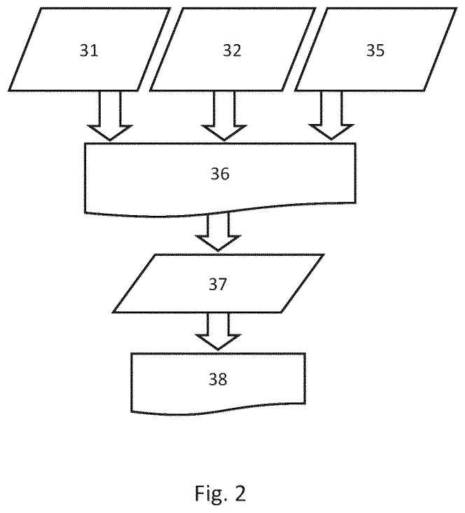

FIG. 2 illustrates an exemplary flow chart for simulating lithography in a lithographic projection apparatus, according to an embodiment of the present disclosure. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (o) settings as well as any particular illumination shape (e.g., off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

$$CF ( {z}_{1} , {z}_{2} , … , {z}_{N} ) = {\sum }_{p = 1}^{p} {w}_{p} {f}_{p}^{2} ( {z}_{1} , {z}_{2} , … , {z}_{N} ) \qquad ( Eq . 1 )$$

where (z₁, z₂, . . . , z_{N}) are N design variables or values thereof. fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF (z₁, z₂, . . . , z_{N}) is not limited to the form in Eq. 1. CF (z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ(z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N}) E Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “patterning process” means a process that creates an etched substrate by the application of specified patterns of light as part of a lithography process.

As used herein, the term “target pattern” means an idealized pattern that is to be etched on a substrate.

As used herein, the term “printed pattern” means the physical pattern on a substrate that was formed based on a design layout. The printed pattern can include, for example, vias, contact holes, troughs, channels, depressions, edges, or other two and three dimensional features resulting from a lithography process.

As used herein, the term “process model” means a model that includes one or more models that simulate a patterning process. For example, a process model can include any combination of: an optical model (e.g., that models a lens system/projection system used to deliver light in a lithography process and may include modelling the final optical image of light that goes onto a photoresist), a mask model, a resist model (e.g., that models physical effects of the resist, such as chemical effects due to the light), an OPC model (e.g., that can be used to make design layouts and may include sub-resolution resist features (SRAFs), etc.), an imaging device model (e.g., that models what an imaging device may image from a printed pattern).

As used herein, the term “imaging device” means any number or combination of devices and associated computer hardware and software that can be configured to generate images of a target, such as the printed pattern or portions thereof. Non-limiting examples of an imaging devices can include: scanning electron microscopes (SEMs), x-ray machines, etc.

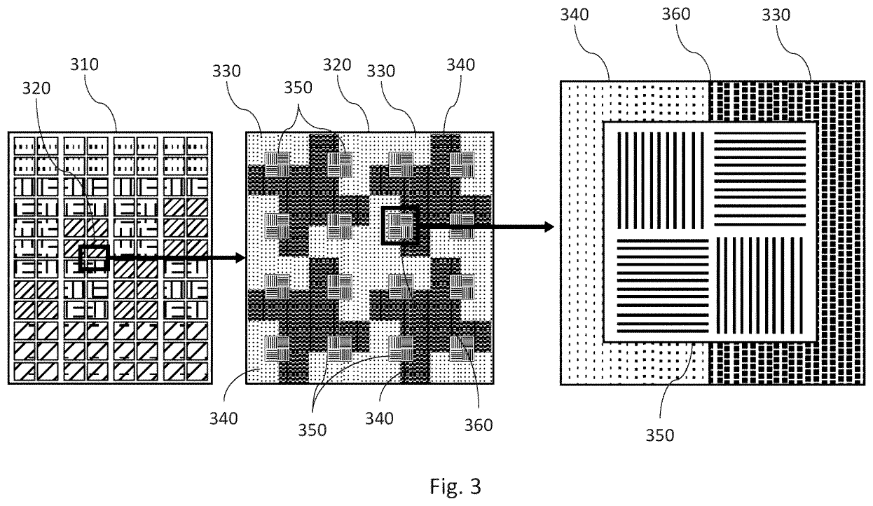

FIG. 3 illustrates metrology marks on a die having varying pattern densities, according to an embodiment of the present disclosure. Metrology marks can be physical features etched into the substrate of a die that has been printed with the lithographic methods described herein. Metrology marks can be utilized to provide points of reference that can be detected and measured by metrology systems (e.g., scanning electron microscopes, optical devices, etc.). Metrology marks can be utilized to determine die-to-die variations, with such variations possibly indicating manufacturing errors or other process effects that may need correcting. Metrology marks can also be implemented at different layers of a die and therefore can be utilized to determine overlay or other level-dependent features.

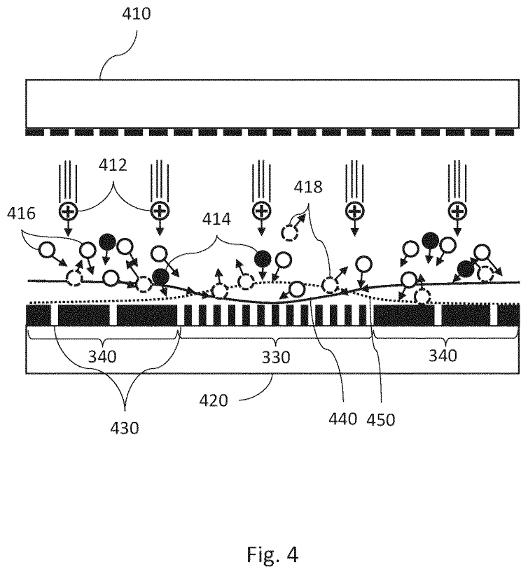

In the example shown in FIG. 3, die 310 is depicted as having a complex printed pattern. Region 320 is shown in an expanded view and depicts different areas of die 310 having different pattern densities (e.g., where there may be more or fewer etched features in a given area), for example, high-density regions 330 and low-density regions 340. In this particular example the high-density region has low open area compared to low-density region. However, in a different example as shown in FIG. 4, it is vice versa, where high-density region 330 is also the high open area region. Also shown are metrology marks 350 that can span boundaries between various high-density regions 330 and low-density regions 340. In other embodiments metrology marks may be entirely withing a region having a consistent pattern density, or otherwise may be disposed anywhere within a die and at any layer.

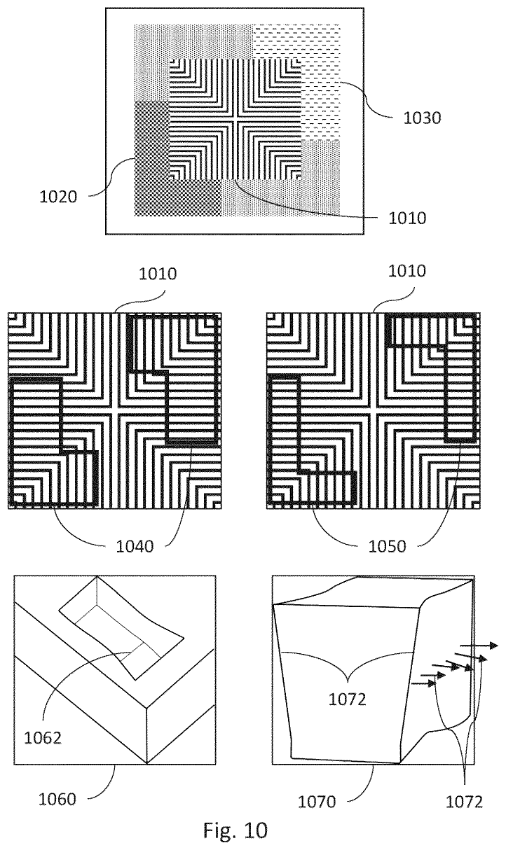

Expanded view 360 of a single metrology mark 350 shows one example of a metrology mark design where the metrology mark can include a number of features such as lines that may be etched out in the die. While metrology mark 350 is one example design, different embodiments can utilize different designs (see, e.g., the designs shown in FIG. 10). While the etching process for creating metrology marks may call for nominally identical features (e.g., each line may be intended to be the same), lines may be proximate to regions of die 350 that can have different pattern densities, and this can cause variations in the etch rate when forming the metrology mark. Such variations can then interfere with use of the metrology mark as an accurate reference point. Various embodiments of the present disclosure provide methods for optimizing metrology marks to reduce such variations. Because the variations may be caused by changes in etch rate due to local pattern features and may only occur over a limited spatial extent, such variations can manifest as asymmetries in what might be an otherwise symmetric mark. Thus, as used herein, the term “asymmetry” is generally synonymous with the term “variation.”

FIG. 4 illustrates a simplified etching process, according to an embodiment of the present disclosure. Plasma etching is depicted in FIG. 4 by showing an example plasma source 410 that generates charged species (ions) 412 and uncharged species 414 (neutrals and radicals) from a supply etch gas 416 (e.g., reactive gases diluted with inert gases). Ions 412 and uncharged species 414 together form an etchant that reacts with the surface of substrate 420 (where not protected by a resist layer) and causes removal of material from substrate 420 in the form of emissions 418. Features 430 are then etched out from substrate 420 by removal of the emissions 418. The emitted species 418 could be volatile by-products or involatile products that are redeposited elsewhere. As shown, the features can have high density regions 330 and low-density regions 340 analogous to those depicted in FIG. 3.

FIG. 4 also depicts the etchant concentration 440 and emission concentration 450. Etchant concentration 440 can be lower in the high open area region 330 and emission concentration 450 can be lower in low-open area region 340. This can occur because the etchant consumption can be higher in high-open area regions. Accordingly, the etch rate can thereby be a function of the local open area and hence indirectly dependent on the pattern density.

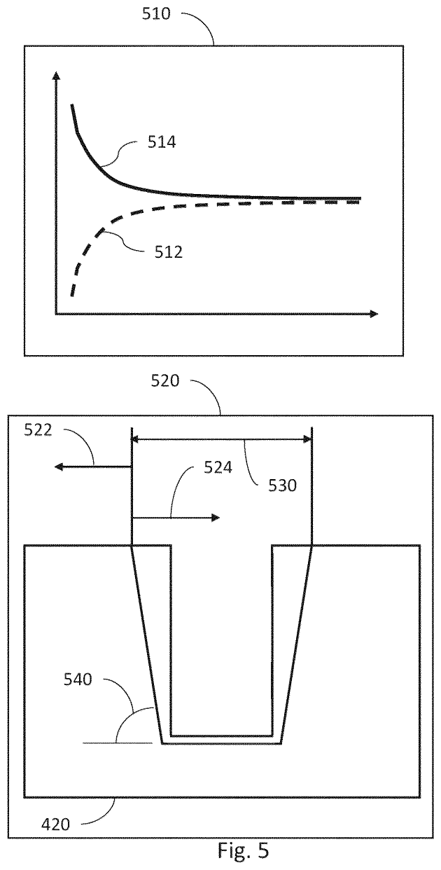

FIG. 5 illustrates the effect of feature size on etch rate, according to an embodiment of the present disclosure. Another process that can affect etch rate can be the etch chemistry itself. Plot 510 depicts etch rate versus feature size (e.g., critical dimension or CD). “Normal lag” 512 is depicted by the bottom dashed curve and shows that with lean chemistry (e.g., a plasma rich in fluorine based radicals) that the etch rate increases with CD because when the CD is larger, there can be more access to etchants and easier removal of etch byproducts. However, there may be other process gases that are rich in CFₓ based polymerizing species) that have the opposite behavior-etch rate decreases with CD. This can be due to the fluorocarbon etchants passivating the feature and causing the etch rate to decrease as the CD increases. Such “reverse lag” 514 behavior is depicted by the upper solid curve. Plot 520 depicts passivation and how the combination of these chemical processes can act to increase or decrease the CD 530. When the etchant is composed more of fluorine radicals (Fₓ), this can cause CD expansion 522. However, the contribution of passivating species (e.g., CFₓ) and/or emitted species (SiFₓ—combination of the silicon substrate material and the fluorine gas), can cause CD contraction 524. The change in CD spatially due to normal or reverse lag effect can be the result of microloading. Accordingly, there can be different extents of passivation as a function of feature depth and can therefore cause the etch rate to be higher near the top of a feature. Among other effects, this can cause the feature to have a side wall angle 540 different from the ideal angle of 90 degrees.

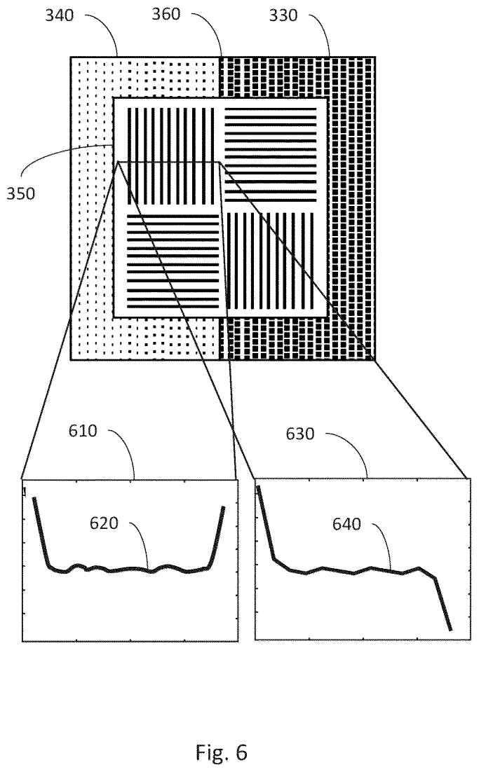

FIG. 6 illustrates the effect of neighboring pattern density on etch performance of a metrology mark, according to an embodiment of the present disclosure. The physical etch processes described above can contribute to variations etch performance, such as CD or overlay (OVL), for the features present in any particular metrology mark. The expanded view 360 of metrology mark 350 depicted in FIG. 3 is reproduced in FIG. 6.

Also shown is plot 610 and 630 depicting an example of CD variation 620 and OVL variation 640 due to such etch-induced process effects. In this example, the CD and OVL variations depict the CD (e.g., width of the line features in metrology mark 350) and OVL taken across the lines as fairly constant except at the outer two lines that have substantial variation. Such variation can be the result of differences in etch rate as described above.

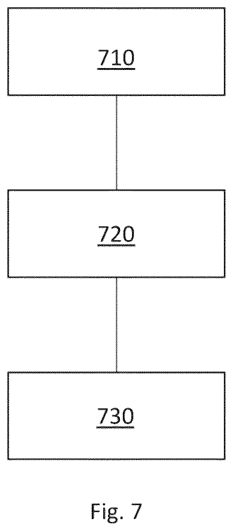

FIG. 7 illustrates a process for optimizing a metrology mark, according to an embodiment of the present disclosure. The method depicted in FIG. 7 can reduce variations due to the physical etch processes described herein. At 710, the method can include simulating an etch process based on one or more of a pattern density, a microloading effect induced intra-mark variation, or a sensitivity of intra-mark variation to etch chemistry. Pattern density is described above and again refers to the local density of features (as shown in the example of FIGS. 3 and 4) that may impact the etch rate, such as due to the local consumption of etchants. “Microloading effect induced intra-mark variation” refers to variations across the metrology mark due to microloading (as shown in the example of FIG. 4). In various embodiments, the microloading effect induced intra-mark variation can include a CD or a side wall angle or floor tilt of the metrology mark being larger or smaller than an ideal metrology mark. An example of such a variation was depicted in FIG. 5 by showing the side wall angle 540. The microloading effect induced intra-mark variation can be based at least on the pattern density. This can be understood from the features of the metrology mark having different proximities to areas of lower/higher pattern density, which has been explained herein to affect the etch rate due to, for example, the differential depletion of etchants. “Sensitivity of intra-mark variation to etch chemistry” refers to the variations in etch rate based on the chemical composition and/or relative concentrations of etchants that may govern the etch rate as a function of CD (as shown by the example of FIG. 5 and further described below with reference to improving simulation of the microloading effect.

At 720, the method can include predicting etch-induced process effects on the metrology mark based on the simulation of the etch process. Predictions can be generated by computational simulation of the physical and chemical processes affecting etch rate as described herein.

At 730, the method can include optimizing the metrology mark based on the predicted etch-induced process effects. Optimizing metrology marks can include a number of iterative processes whereby different designs and/or locations of metrology marks can be simulated for a given etch process. The performance of the metrology marks can be evaluated while varying the metrology marks, etch chemistries, etching processes, or any other aspects of the lithography process to select/place optimal metrology marks.

In some embodiments, an etch rate in the simulation can be based at least partially on a function of a CD with coefficients in the function being dependent on the etch chemistry. For example, a model for simulating the microloading effect can be written as:

$${J}_{q} = {D}_{q} ∇ {α}_{q} \vert {G}_{q} ( λ ) * {L}_{q} ( ρ , E ) \vert \qquad Eq . 2$$

where J_{q} is a flux of etchant species q which can be calculated using a multiscale gradient convolution, G is a Gaussian kernel, λ is a mean free path, and L is the etch load and depends on perimeter map r and on the CD-dependent etch rate E. The function E can be represented as an exponential term having coefficients where the function determines, in part, an etch load for the etch process. In particular, E can be expressed as:

$$E ( CD ) = {E}_{0} + {ae}^{b CD} . \qquad Eq . 3$$

where E₀ is the target etch rate and the coefficients a and b can depend on etch chemistry and, for example, can be determined empirically by measurements of changes in CD and/or etch rate given various metrology marks, local conditions, etch chemistries, etc. Determining the sensitivity of intra-mark variation to etch chemistry can include determining an etch rate based on the etch regime being normal lag or reverse lag as determined by the etch chemistry, which can be reflected in Eq. 3, above.

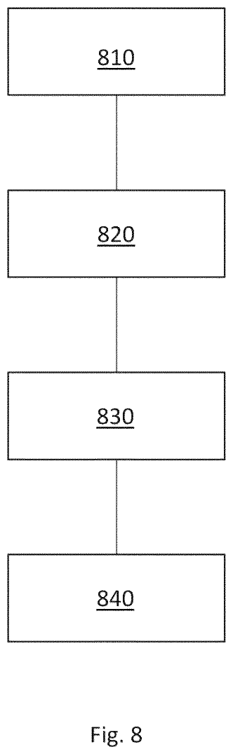

FIG. 8 illustrates a process for optimizing a metrology mark placement, according to an embodiment of the present disclosure. Some embodiments for optimizing the metrology mark can include optimizing a metrology mark placement based on an intra-die overlay fingerprint produced from the simulating of the etch process at a first length scale. Intra-die overlay fingerprint refers to a characteristic variation between determined overlays within a die. For example, in the ideal case the overlay between different levels of a printed die would be zero. However, in reality there may be some overlay and the determination of such overlay can be based on measuring metrology marks. Where metrology marks have variations due to etch processes this can affect accurate determination of overlays. Examples of first length scales that can be utilized include those between 0.1 and 10 μm, for example, 1, 2, or 5 μm. The use of such comparatively large length scales can facilitate rapid simulation when determining metrology mark placement and determining the resultant overlays.

In the embodiment shown in FIG. 8, one example process can include, at 810, obtaining a metrology mark design and the metrology mark placement in a die. Such initial design and placement can be based on libraries of different metrology mark designs and preset locations for metrology mark placement. At 820, the process can include inputting the metrology mark design into the simulation at the first length scale. At 830, the process can include extracting critical zones in a die based on the intra-die overlay fingerprint determined by the simulation. For example, the locations in the die where it is sub-optimal or prohibited to place a metrology mark based on the intra die overlay fingerprint. Such locations can be “critical locations” and can be excluded by the optimization process when optimizing metrology mark design and/or placement. At 840, the process can include optimizing the metrology mark placement, while avoiding the critical zones, to minimize the intra-die overlay fingerprint. For example, the intra-die overlay fingerprint can be parameterized by a deviation from an optimal cumulative overlay. Simulation of resultant metrology marks of different designs and/or placements can then cover a parameter space where the optimal metrology mark placement can be taken as minimizing such deviations (or fingerprints).

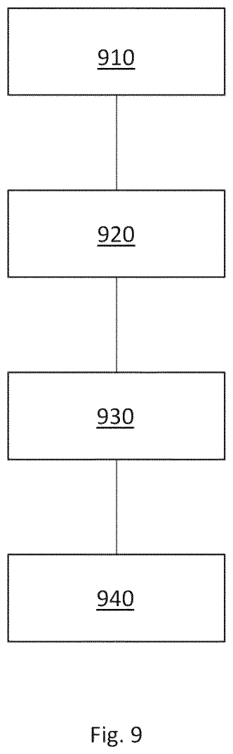

FIG. 9 illustrates a process for optimizing a metrology mark design, according to an embodiment of the present disclosure. Some embodiments for optimizing the metrology mark design be based on an intra-mark overlay fingerprint produced from the simulating the etch process at a second length scale. Examples of second length scales that can be utilized include those between 0.1 and 10 nm, for example, 1, 2, or 5 nm. The use of such comparatively small length scales can facilitate accurate simulation that account for local pattern densities, which may be on nanometer or even sub-nanometer length scales. FIG. 9 depicts a process that may be utilized for such optimization of the metrology mark design. However, the detailed process set forth FIG. 9 need not be necessarily utilized in combination with the detailed process set forth in FIG. 8, and vice versa. Accordingly, various embodiments of the present disclosure can include generally optimizing metrology mark placement at a first length scale and optimizing metrology mark design at a second length scale, with either optimization optionally enhanced by the detailed processes of FIGS. 8 and 9.

The detailed process depicted in FIG. 9 can include, for example, at 910, obtaining the metrology mark design and the metrology mark placement in a die. At 920 the process can include inputting the metrology mark design into the simulation at the second length scale. At 930, the process can include extracting the intra-mark overlay fingerprint from the simulation at the second length scale. At 940, the process can include optimizing the metrology mark design to reduce the intra-mark overlay fingerprint.

In some embodiments, multiscale convolution is performed based on different physics of various scales. In some embodiments, superposition of the different physics of multiple length scales is used, where each length scale corresponds to different physics effects or physics aspect. The different physics effects in the multiscale convolution may include pattern-perimeter-density induced (1) microloading effect due to etchant flux variation that induces process asymmetries; (2) electrical effects due to surface charging and hence plasma sheath variation that causes ion-tilt induced etch non-uniformities; (3) stress effects that can cause mark deformation, etch non-uniformity, overlay issues; and/or (4) Other physical effects that may cause undesired effects such as etch non-uniformity, poor overlay.

Various aspects of the metrology mark design and placement can be included in the simulation. For example, some embodiments, the metrology mark design can be based on one or more of a CD, pitch, segmentation, or surrounding fill structures. The simulation can be further based on inputting stack information of the metrology mark design, the stack information including layers in the die. The inputting of the metrology mark design can also include determining an etch regime, where the simulation can be based on the etch regime being normal lag or reverse lag.

Similarly, optimizing of the metrology mark placement can include optimizing one or more of a CD, pitch, design, and segmentation of the metrology mark. Also, optimizing of the metrology mark placement can also include optimizing a surrounding fill pattern to reduce an intra-mark variation. Optimizing the surrounding fill pattern integrating the etch simulation with simulations of the lithography process itself (e.g., mask/resist simulation, aerial image simulation, etc.).

FIG. 10 is a diagram illustrating a metrology mark with variations in CD, floor tilt and side wall angle, according to an embodiment of the present disclosure. FIG. 10 depicts an example of a metrology mark 1010 with an adjacent high-density region 1020 and low-density region 1030. The simulations described herein that incorporate applying physical effects such as due to etch chemistry can cause regions where the geometry (e.g., floor tilt, side wall angle, etc.) of the metrology mark deviates from the ideal. FIG. 10 depicts metrology mark 1010 having examples of regions where such asymmetries may occur. Asymmetric floor tilt region 1040 can be regions of metrology mark 1010 that have variations in floor tilt (i.e., deviations from an etched feature having a flat bottom surface that may be ideal or expected from an etching process). Variations in floor tilt can affect metrology measurements and optical wafer alignment metrology may be utilized for overlay control. This can include accurate measurement of the geometric center, or point-of-interest (POI), of an optical grating structure. However, when the optical grating structure-based alignment marks have floor tilt, post etching, the measurement of geometric center can deviate from the POI. Floor tilt region 1040 can be represented by a floor tilt map, which may be a contour map (capturing height/depth in the mark), discrete data points for the height/depth, surface normal vectors, etc.

Similarly, metrology mark 1010 can have an asymmetric sidewall tilt region 1050 where there may be variations in the side wall angle that can affect CD measurements, etc. Side wall angles can be parameterized as side wall angle vectors. Side wall angle vectors may be implemented as a side wall angle map showing the vectors representing the normal to the respective side walls. Features present in metrology mark 1010 can be modeled with a 3D geometry engine to provide a full representation of the metrology mark. One example of a feature is also shown in FIG. 10, where diagram 1060 depicts a perspective view looking down into a feature and showing that there is a floor tilt 1062 present causing a peaking in the floor of the feature. Diagram 1070 shows the inverse of the feature shown in diagram 1060 that depicts the feature having a side wall angle 1072 and examples of side wall angle vectors 1072.

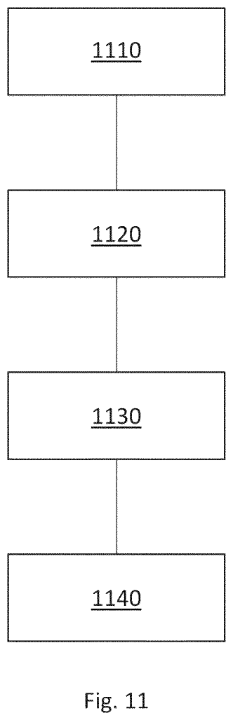

FIG. 11 is a diagram illustrating a process for optimizing a metrology mark design, according to an embodiment of the present disclosure. The modelling of the simulated metrology mark, for example as described with regard to FIG. 10, can be implemented by various processes disclosed herein. One example process is depicted in FIG. 11 and can include, at 1110 inputting ideal metrology marks. Ideal metrology marks can include those that might be designed to have exacting shapes, vertical side walls, flat floors, etc. Such ideal metrology marks can be represented by GDS data files and stored in libraries or databases of metrology marks, or other similar data storage methods. In another embodiment, the input can be an after-developed geometry of the metrology mark.

At 1120, the process can include determining a floor tilt map, a side wall angle map, a CD map, and a etch depth map based on the predicting of the etch-induced process effects for each of the ideal metrology marks. The determining of such maps can include the simulations described herein that account for microloading effects, local pattern density, etc.

At 1130, the process can include generating three-dimensional representations of the after-etched mark geometry based on the floor tilt map, the side wall angle map, the CD map, and the etch depth map.

At 1140, the process can include determining a combination of the ideal metrology marks that improve a performance of a die utilizing the combination, the performance determined based at least on the three-dimensional representations. Such combinations can be robust to etch process variations and can thereby improve the performance of the die.

Some embodiments that utilize such methods to improve the performance of the die can include reducing an alignment position deviation. The performance can be determined utilizing a finite-difference time domain optical solver that can take the three-dimensional representations and quantify the variations of the simulated etched features. With determinations of the performance of the metrology marks, the metrology marks can be optimized or selected to provide improvements in the ability of such metrology marks to facilitate analysis of printed dies.

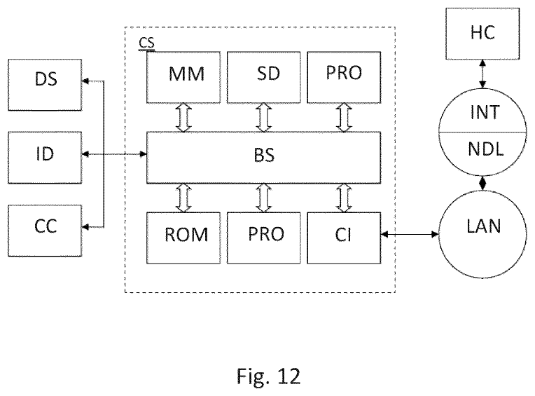

FIG. 12 is a block diagram of an example computer system CS, according to an embodiment of the present disclosure.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

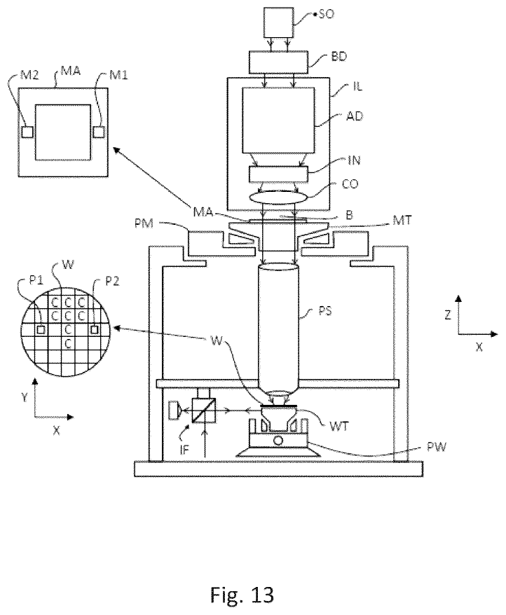

FIG. 13 is a schematic diagram of a lithographic projection apparatus, according to an embodiment of the present disclosure.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning apparatuses, such as a beam expander Ex, for example. The illuminator IL may comprise adjusting device AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning apparatus (and interferometric measuring apparatus IF), the substrate table WT can be moved accurately, e.g., so as to position different target portions C in the path of beam PB. Similarly, the first positioning apparatus can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=1/4 or 1/5). In this manner, a relatively large target portion C can be exposed, without having to compromise on resolution.

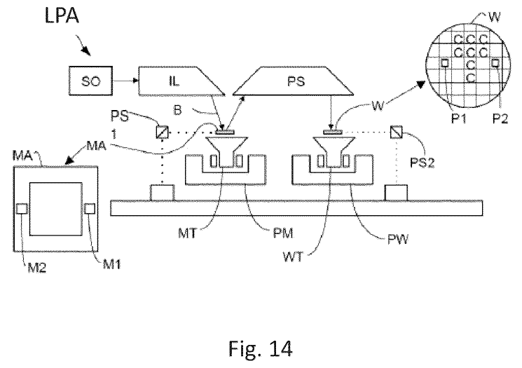

FIG. 14 is a schematic diagram of another lithographic projection apparatus (LPA), according to an embodiment of the present disclosure.

LPA can include source collector module SO, illumination system (illuminator) IL configured to condition a radiation beam B (e.g., EUV radiation), support structure MT, substrate table WT, and projection system PS.

Support structure (e.g., a patterning device table) MT can be constructed to support a patterning device (e.g., a mask or a reticle) MA and connected to a first positioner PM configured to accurately position the patterning device;

Substrate table (e.g., a wafer table) WT can be constructed to hold a substrate (e.g., a resist coated wafer) W and connected to a second positioner PW configured to accurately position the substrate.

Projection system (e.g., a reflective projection system) PS can be configured to project a pattern imparted to the radiation beam B by patterning device MA onto a target portion C (e.g., comprising one or more dies) of the substrate W.

As here depicted, LPA can be of a reflective type (e.g., employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g., patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g., patterning device table) MT and the substrate table WT are scanned synchronously while a pattern imparted to the radiation beam is projected onto target portion C (i.e. a single dynamic exposure). The velocity and direction of substrate table WT relative to the support structure (e.g., patterning device table) MT may be determined by the (de-)magnification and image reversal characteristics of the projection system PS.

In stationary mode, the support structure (e.g., patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

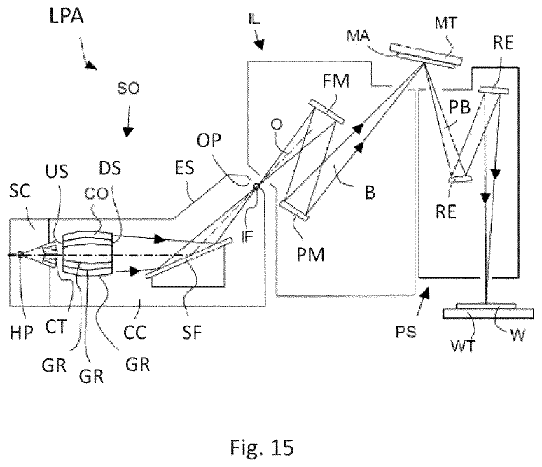

FIG. 15 is a detailed view of the lithographic projection apparatus, according to an embodiment of the present disclosure.

As shown, LPA can include the source collector module SO, the illumination system IL, and the projection system PS. The source collector module SO is constructed and arranged such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘O’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device PM arranged to provide a desired angular distribution of the radiation beam B, at the patterning device MA, as well as a desired uniformity of radiation amplitude at the patterning device MA. Upon reflection of the beam of radiation B at the patterning device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

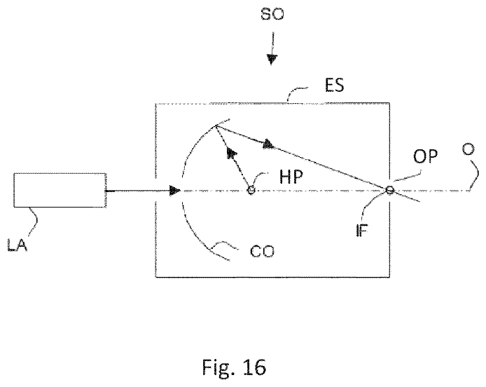

FIG. 16 is a detailed view of source collector module SO of lithographic projection apparatus LPA, according to an embodiment of the present disclosure.

Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The concepts disclosed herein may simulate or mathematically model any generic imaging system for imaging sub wavelength features and may be especially useful with emerging imaging technologies capable of producing increasingly shorter wavelengths. Emerging technologies already in use include EUV (extreme ultraviolet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

Embodiments of the present disclosure may be further described by the following clauses.
1. A method of optimizing a metrology mark, the method comprising:
   simulating an etch process based on one or more of a pattern density, a microloading effect induced intra-mark variation, or a sensitivity of intra-mark variation to etch chemistry;
   predicting etch-induced process effects on the metrology mark based on the simulation of the etch process; and
   optimizing the metrology mark based on the predicted etch-induced process effects.
2. The method of clause 1, wherein an etch rate in the simulation is based at least partially on a function of a CD with coefficients in the function being dependent on the etch chemistry.
3. The method of clause 2, wherein the function is an exponential term having the coefficients, the function determining, in part, an etch load for the etch process.
4. The method of clause 1, wherein the microloading effect induced intra-mark variation includes a CD or a side wall angle or floor tilt of the metrology mark being larger or smaller than an ideal metrology mark.
5. The method of clause 3, wherein the microloading effect induced intra-mark variation is based on the pattern density.
6. The method of clause 1, wherein determining the sensitivity of intra-mark variation to etch chemistry comprises determining an etch rate based on the etch regime being normal lag or reverse lag as determined by the etch chemistry.
7. The method of clause 1, wherein optimizing the metrology mark includes optimizing a metrology mark placement based on an intra-die overlay fingerprint produced from the simulating of the etch process at a first length scale.
8. The method of clause 6, further comprising:
   obtaining a metrology mark design and the metrology mark placement in a die;
   inputting the metrology mark design into the simulation at the first length scale;
   extracting critical zones in a die based on the intra-die overlay fingerprint determined by the simulation; and
   optimizing the metrology mark placement, while avoiding the critical zones, to minimize the intra-die overlay fingerprint.
9. The method of clause 7, wherein the metrology mark design is based on one or more of a CD, pitch, segmentation, or surrounding fill structures.
10. The method of clause 7, wherein the simulation is further based on inputting stack information of the metrology mark design, the stack information including layers in the die.
11. The method of clause 7, the inputting of the metrology mark design further comprising determining an etch regime, wherein the simulation is based on the etch regime being normal lag or reverse lag.
12. The method of clause 6, wherein the optimizing the metrology mark includes optimizing a metrology mark design based on an intra-mark overlay fingerprint produced from the simulating the etch process at a second length scale.
13. The method of clause 9, further comprising:
   obtaining the metrology mark design and the metrology mark placement in a die;
   inputting the metrology mark design into the simulation at the second length scale;
   extracting the intra-mark overlay fingerprint from the simulation at the second length scale; and
   optimizing the metrology mark design to reduce the intra-mark overlay fingerprint.
14. The method of clause 10, the optimizing of the metrology mark placement further comprising optimizing one or more of a CD, pitch, design, and segmentation of the metrology mark.
15. The method of clause 10, the optimizing of the metrology mark placement further comprising optimizing a surrounding fill pattern to reduce an intra-mark variation.
16. The method of clause 1, further comprising:
   inputting ideal metrology marks;
   determining a floor tilt map, a side wall angle map, a CD map, and a etch depth map based on the predicting of the etch-induced process effects for each of the ideal metrology marks;
   generating three-dimensional representations of the after-etched mark geometry based on the floor tilt map, the side wall angle map, the CD map, and the etch depth map; and determining a combination of the ideal metrology marks that improve a performance of a die utilizing the combination, the performance determined based at least on the three-dimensional representations.
17. The method of clause 11, wherein improving the performance includes reducing an alignment position deviation.
18. The method of clause 11, wherein the performance is determined utilizing a finite-difference time domain optical solver.
19. The method of clause 1, wherein the simulating comprises performing multiscale convolution based on different physics effects of various length-scales.
20. The method of clause 19, wherein the multiscale convolution comprises superposition of physics effects of multiple length scales.
21. The method of clause 20, wherein the different physics effects comprise (1) microloading effect due to etchant flux variation that induces process asymmetries; (2) electrical effects due to surface charging and hence plasma sheath variation that causes ion-tilt induced etch non-uniformities; and/or (3) stress effects that can cause mark deformation, etch non-uniformity, overlay issues.
22. A non-transitory computer readable medium having instructions recorded thereon for optimizing a metrology mark, the instructions when executed by one or more processors cause the one or more processors to perform a method in any of clauses 1-21.
23. A system for optimizing a metrology mark, the system comprising:
   at least one programmable processor; and
   non-transitory computer readable medium having instructions recorded thereon for optimizing a metrology mark, the instructions when executed by one or more processors cause the one or more processors to perform a method as described in any of clauses 1-21.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The combinations and sub-combinations of the elements disclosed herein constitute separate embodiments and are provided as examples only. Also, the descriptions above are intended to be illustrative, not limiting. Thus, it will be apparent to one skilled in the art that modifications may be made as described without departing from the scope of the claims set out below.

1. A non-transitory computer readable medium having instructions recorded thereon or therein, the instructions, when executed by one or more processors, configured to cause the one or more processors to at least:
simulate an etch process based on one or more selected from: a pattern density, a microloading effect induced intra-mark variation, or a sensitivity of intra-mark variation to etch chemistry;
predict etch-induced process effects on the metrology mark based on the simulation of the etch process; and
optimize the metrology mark based on the predicted etch-induced process effects.

2. The medium of claim 1, wherein an etch rate in the simulation is based at least partially on a function of a CD with coefficients in the function being dependent on the etch chemistry.

3. The medium of claim 1, wherein the simulation is based on a microloading effect induced intra-mark variation and the microloading effect induced intra-mark variation includes a CD or a side wall angle or floor tilt of the metrology mark being larger or smaller than an ideal metrology mark.

4. The medium of claim 1, wherein the simulation is based on a microloading effect induced intra-mark variation and the microloading effect induced intra-mark variation is determined based on the pattern density.

5. The medium of claim 1, wherein the simulation is based on a sensitivity of intra-mark variation to etch chemistry and an etch rate in the simulation is based on the etch regime being normal lag or reverse lag as determined by the etch chemistry.

6. The medium of claim 1, wherein the instructions configured to cause the one or more processors to optimize the metrology mark are further configured to cause the one or more processors to optimize a metrology mark placement based on an intra-die overlay fingerprint produced from the simulating of the etch process at a first length scale.

7. The medium of claim 6, wherein the instructions are further configured to cause the one or more processors to:
obtain a metrology mark design and the metrology mark placement in a die;
input the metrology mark design into the simulation at the first length scale;
extract critical zones in a die based on the intra-die overlay fingerprint determined by the simulation; and
optimize the metrology mark placement, while avoiding the critical zones, to minimize the intra-die overlay fingerprint.

8. The medium of claim 7, wherein the metrology mark design is based on one or more selected from: a CD, pitch, segmentation, or surrounding fill structures, and wherein the simulation is further based on input of stack information of the metrology mark design, the stack information including layers in the die, and wherein the input of the metrology mark design further comprises determination of an etch regime, wherein the simulation is based on the etch regime being normal lag or reverse lag.

9. The medium of claim 6, wherein the instructions configured to cause the one or more processors to optimize the metrology mark are further configured to cause the one or more processors to optimize a metrology mark design based on an intra-mark overlay fingerprint produced from the simulation of the etch process at a second length scale.

10. The medium of claim 9, wherein the instructions are further configured to cause the one or more processors to:
obtain the metrology mark design and the metrology mark placement in a die;
input the metrology mark design into the simulation at the second length scale;
extract the intra-mark overlay fingerprint from the simulation at the second length scale; and
optimize the metrology mark design to reduce the intra-mark overlay fingerprint, wherein the optimization of the metrology mark placement further comprises optimization of one or more selected from: a CD, pitch, design, or segmentation of the metrology mark.

11. The medium of claim 1, wherein the instructions are further configured to cause the one or more processors to:
input ideal metrology marks;
determine a floor tilt map, a side wall angle map, a CD map, and a etch depth map based on the prediction of the etch-induced process effects for each of the ideal metrology marks;
generate three-dimensional representations of the after-etched mark geometry based on the floor tilt map, the side wall angle map, the CD map, and the etch depth map; and
determine a combination of ideal metrology marks from the ideal metrology marks that improve a performance of a die utilizing the combination, the performance determined based at least on the three-dimensional representations.

12. The medium of claim 11, wherein the instructions configured to cause the one or more processors to improve the performance are further configured to cause the one or more processors to reduce an alignment position deviation, and wherein the performance is determined utilizing a finite-difference time domain optical solver.

13. The medium of claim 1, wherein the instructions configured to cause the one or more processors to simulate the etch process are further configured to cause the one or more processors to perform multiscale convolution based on different physics effects of multiple length-scales.

14. The medium of claim 13, wherein the multiscale convolution comprises superposition of physics effects of multiple length-scales.

15. The medium of claim 14, wherein the different physics effects comprise (1) microloading effect due to etchant flux variation that induces process asymmetries; (2) electrical effects due to surface charging and hence plasma sheath variation that causes ion-tilt induced etch non-uniformities; and/or (3) stress effects that can cause mark deformation, etch non-uniformity, or overlay issues.

16. A method comprising:
simulating, by a hardware computer system, an etch process based on one or more selected from: a pattern density, a microloading effect induced intra-mark variation, or a sensitivity of intra-mark variation to etch chemistry;
predicting etch-induced process effects on the metrology mark based on the simulation of the etch process; and
optimizing the metrology mark based on the predicted etch-induced process effects.

17. The method of claim 16, wherein an etch rate in the simulation is based at least partially on a function of a CD with coefficients in the function being dependent on the etch chemistry.

18. The method of claim 16, wherein the simulation is based on a microloading effect induced intra-mark variation and the microloading effect induced intra-mark variation includes a CD or a side wall angle or floor tilt of the metrology mark being larger or smaller than an ideal metrology mark.

19. The method of claim 16, wherein the simulation is based on a microloading effect induced intra-mark variation and the microloading effect induced intra-mark variation is determined based on the pattern density.

20. The method of claim 16, wherein the simulation is based on a sensitivity of intra-mark variation to etch chemistry and an etch rate in the simulation is based on the etch regime being normal lag or reverse lag as determined by the etch chemistry.
